(19) United States
(12) Patent Application Publication
(10) Pub. No.: US 2014/0072701 A1
(43) Pub. Date: Mar. 13, 2014

(54) COMPOSITION FOR AN FPCB COVERLAY AND METHOD FOR PRODUCING THE SAME

(71) Applicant: PICOMAX CO., LTD., Seoul (KR)

(72) Inventor: Jong Seok SONG, Seoul (KR)

(73) Assignee: PICOMAX CO., LTD., Seoul (KR)

(21) Appl. No.: 13/961,769

(22) Filed: Aug. 7, 2013

(30) Foreign Application Priority Data
Sep. 7, 2012 (KR) 10-2012-0099344

(51) Int. Cl. H05K 1/03; H05K 3/28

(52) U.S. Cl. CPC H05K 1/0373; H05K 3/28
USPC 427/98.4; 524/600

(57) ABSTRACT

A composition for a coverlay having superior thermal resistance, flexibility, and electrical properties, as well as a method of producing the coverlay and a method of forming the coverlay on a PCB are provided. The composition for a coverlay according to an embodiment of the invention may include 10.0˜45.0 wt % of polyimide, 0.01˜5.0 wt % of a defoaming agent, 0.01˜5.0 wt % of a leveling agent, 0.01˜5.0 wt % of a dispersing agent, 0.1˜15.0 wt % of modified polyimide, and a remainder of a solvent. Also provided is a method for producing a composition for a coverlay for an FPCB that includes: placing amine and an acid anhydride in a reaction solvent and subjecting to first polymerization; placing an acid anhydride in a separate reaction solvent subjecting to second polymerization; forming a polyamic acid by mixing a product of the first polymerization with a product of the second polymerization; and adding a defoaming agent, a leveling agent, a dispersing agent, and modified polyimide to the polyamic acid. Also provided is a method of forming a polyimide coverlay on an FPCB that includes: preparing a mask over a circuit of an FPCB, the mask having a desired printing pattern; applying the liquid polyimide composition of claim 1 over an opening of the mask; and curing the PCB having the polyimide composition applied thereto.

### CROSS-REFERENCE TO RELATED APPLICATIONS

This application claims the benefit of Korean Patent Application No. 10-2012-0099344, filed with the Korean Intellectual Property Office on Sep. 7, 2012, the disclosure of which is incorporated herein by reference in its entirety.

### BACKGROUND

1. Technical Field

The present invention relates to a composition for an FPCB (flexible printed circuit board) coverlay and a method for producing the coverlay, more particularly to a composition for a coverlay and method for producing the coverlay that can simplify the manufacturing process and can provide a coverlay having superior thermal, flexible, and electrical properties.

2. Description of the Related Art

A printed circuit board uses solder resist to protect the circuits after circuit patterning. The properties important in solder resist include those related to circuit protection, insulation, thermal resistance, etc. Solder resist is used in most types of printed circuit boards, including the single-sided PCB, the multi-layered PCB, the package PCB, and the rigidflex PCB. After curing, solder resist becomes rigid and is deprived of its flexibility.

However, the FPCB (flexible printed circuit board), which requires 3-dimensional wiring, may employ a coverlay film instead of solder resist as the material for circuit protection. Manufacturers of FPCB's may form a circuit pattern on a flexible copper clad laminate (FCCL) and attach an insulative film, i.e. the coverlay film, to produce an FPCB. The coverlay film possesses a flexible property and may be composed of a polyimide film and an epoxy adhesive layer. Thus, the coverlay may be applied for the same purpose as the solder resist (SR) in a rigid PCB, as an element for protecting circuits.

FIG. 3 illustrates the structure of a typical coverlay film according to the related art. The two-layer structure includes PI and adhesive (for example, a structure having epoxy coated over a polyimide film). Generally, the PI (polyimide) layer is 12˜25 μm and the adhesive layer is 25 μm, making the total thickness of the PI/adhesive arrangement 37˜50 μm.

As illustrated in FIG. 4, however, this structure may require various processes, such as molding and punching, provisional attachment, integration, etc. The punching operation may incur costs associated with molding, while the provisional attachment may require manual operations using a soldering iron on the punched coverlay film. The permanent attachment may be performed during the integration (hot pressing) process. In this case, the process times may be about 30 minutes for the molding, 30˜60 minutes for the provisional attachment, and 90 minutes for the integration, amounting to about 3 hours for the overall process. This may considerably lower productivity.

Moreover, in a conventional coverlay film, polyimide has a high thermal resistance of 280° C. whereas epoxy has a low thermal resistance of 150° C., and as such, the coverlay film is lacking in overall thermal stability. Because of this, the stripping of the circuits may occur during the hot pressing process for integration. Furthermore, while the polyimide layer has superior flexibility and electrical properties, the epoxy used as the adhesive layer has low flexibility and electrical properties, resulting in reduced values for the properties overall.

Furthermore, when using conventional polyimide, bubbles may occur, or the polyimide may adhere to the mask mesh used for printing, and with one, two or more repetitions, the mesh may become blocked, and it may become impossible to continue with the printing. Also, the FPCB may be subject to bubbles formed in the surface, thickness deviations, and shape discrepancies.

### SUMMARY

To resolve the problems described above, an objective of the invention is to provide a composition for a coverlay having superior thermal resistance, flexibility, and electrical properties, as well as a method of producing the coverlay and a method of forming the coverlay on a PCB.

The objective of the invention described above can be achieved with a composition for an FPCB coverlay described below:

a polyimide composition comprising 10.0˜45.0 wt % of polyimide, 0.01˜5.0 wt % of a defoaming agent, 0.01˜5.0 wt % of a leveling agent, 0.01˜5.0 wt % of a dispersing agent, 0.1˜15.0 wt % of modified polyimide, and a remainder of a solvent.

In the liquid polyimide composition, the polyimide is added to imbue flexibility, electrical properties, etc. If the content is below 10.0 wt %, the desired thickness cannot be obtained, whereas if the content exceeds 45.0 wt %, the viscosity may be increased excessively, leading to degraded passability through the mask and hence lower workability.

The minimum thickness for producing the polyimide film is 15˜25 μm. If the content of solids is 10 wt % or less, the desired thickness cannot be obtained, whereas if the content of solids is 50 wt % or more, the viscosity may become excessively high, leading to degraded PAA passability of the mask and causing blockage in the mask. For example, if the solids content is 10 wt %, a coating of 100 μm may form a polyimide layer having a thickness of 10 μm, and if the solids content is 45 wt %, a thickness of 45 μm may be formed. If the content of polyimide solid is 10% and thus too low, then the content of the solvent (NMP, DMAC, DMF, xylene, etc.) may be relatively higher, so that a sudden change in temperature may cause the solvent to volatilize, resulting in cracks or bubbles occurring. Thus, since the curing temperature conditions may have to be slowly increased in a stepwise manner, the curing conditions may be complicated, and the curing time may be lengthened. A stable curing condition may be obtained with at least 15˜20 wt %. On the other hand, if the solids occupy 50 wt % or more, the viscosity may be excessively high, causing low workability. The range of solids content that offers good workability would be about 15˜45 wt %.

The defoaming agent may serve to suppress the occurrence of bubbles, and is not limited to a particular type. A content of less than 0.01 wt % may not provide a sufficient defoaming action, whereas a content higher than 5.0 wt % may degrade workability and the electrical properties of the polyimide, and as such, these values may be selected as the lower and upper limits.

The leveling agent may be added to improve the fluidity of the polyimide composition that is to be coated, as well as to increase flatness during drying. The leveling agent is not limited to a particular type, and since a content of less than 0.01 wt % may not provide sufficient leveling action while a content higher than 5.0 wt % may degrade workability and electrical properties, these values may be selected as the lower and upper limits.

The solvent is not limited to a particular type, and NMP, DMAC, DMF, xylene, etc., for example, can be used for the solvent.

In a polyimide composition according to an embodiment of the invention, a dispersing agent may be used in order to promote dispersion, where the range of its content may preferably be 0.01˜5.0 wt %. With a content of less than 0.01 wt %, the effect of the dispersing agent may not be noticeable, and with a content higher than 5.0 wt %, the workability and electrical properties may be degraded. As such, these values may be selected as the lower and upper limits. The dispersing agent is not limited to a particular type.

The modified polyimide may be used to control surface roughness, flowability, and flatness, and may be obtained by placing additive components to polyimide. The range of the content of the added modified polyimide may preferably be 0.1˜15.0 wt %. With a content of less than 0.1 wt % added, the effect may not be noticeable, and with a content higher than 15.0 wt %, the basic properties of polyimide, including electrical properties, flexibility, and thermal resistance, may be degraded. As such, these values may be used as the lower and upper limits.

In order to control the flatness, levelness, and flowability after printing, the composition can additionally include silica. The range of the content of silica may preferably be 1.0˜15.0 wt %. With a content of less than 1.0 wt %, the effect of the addition may not be noticeable, whereas with a content higher than 15.0 wt %, problems may occur in terms of flexibility. As such, these values may be used as the lower and upper limits.

Also, an embodiment of the invention provides the method for producing a composition for a coverlay described below:

a method of producing an FPCB coverlay that includes:

placing amine and an acid anhydride in a reaction solvent and subjecting to first polymerization;

placing an acid anhydride in a separate reaction solvent subjecting to second polymerization;

forming a polyamic acid by mixing a product of the first polymerization with a product of the second polymerization; and

adding a defoaming agent, a leveling agent, a dispersing agent, and modified polyimide to the polyamic acid.

Here, the amounts by which each material is added may preferably be:

polyimide 10.0˜45.0 wt %, defoaming agent 0.01˜5.0 wt %, leveling agent 0.01˜5.0 wt %, dispersing agent 0.01˜5.0 wt %, and modified polyimide 0.1˜15.0 wt %.

In a preferred embodiment of the invention, silica can be further added to the mixture above.

The composition for a coverlay produced according to an embodiment of the invention can be formed on an FPCB by the following method:

a method of forming a polyimide coverlay on an FPCB that includes: preparing a mask over a circuit of an FPCB, the mask having a desired printing pattern;

applying the liquid polyimide composition of claim 1 over an opening of the mask; and

curing the PCB having the polyimide composition applied thereto.

According to an embodiment of the invention, as described above, the process for forming a coverlay can be simplified to a printing process and a curing process, as a result of utilizing the specially implemented coverlay composition based on an embodiment of the invention.

Unlike the conventional coverlay film, which has a two-layered structure (PI/adhesive), the polyimide liquid coverlay according to an embodiment of the invention has a one-layer structure (polyimide) and can thus provide a reduced thickness. In a coverlay having a typical PI/adhesive structure, the polyimide layer is 12˜25 μm, and the adhesive layer is 25 μm. Thus, the total thickness of the PI/adhesive is 37˜50 μm. According to an embodiment of the invention, however, the PI can be applied with a desired thickness within the range of 10˜60 μm. That is, the coating can be applied tantamount to the thickness of the circuit layer, increasing the degree of freedom in design. Due to this feature, the overall thickness can be reduced to the thickness of the polyimide film layer. The degree of freedom may be increased in terms of design, while the flexibility and electrical properties obtained therefrom may also be superior.

According to the embodiments of the invention described above, a coverlay can be produced that has superior thermal resistance, flexibility, and electrical properties, as well as a reduced thickness. Moreover, the manufacturing process can be simplified to the two steps of printing and curing, to improve productivity by reducing manufacturing costs and shortening production times.

### BRIEF DESCRIPTION OF THE DRAWINGS

FIG. 1 is a diagram schematically illustrating a coverlay having a one-layer structure produced according to an embodiment of the invention.

FIG. 2 is a diagram illustrating the processes for forming a coverlay over a PCB according to an embodiment of the invention.

FIG. 3 is a diagram schematically illustrating a coverlay having a two-layer structure produced according to the related art.

FIG. 4 is a diagram illustrating the processes for forming a coverlay over a PCB according to the related art.

### DETAILED DESCRIPTION

The technical spirit of the present invention will be described below in more detail using a preferred embodiment.

To prepare a composition for a coverlay according to an embodiment of the invention, polyimide may first be synthesized. Polyimide is a polymer resin formed by polymerizing an acid anhydride and amine. The preparation of the polyimide may include first polymerizing an acid anhydride with diamine monomers to synthesize a polyamic acid (PAA), and including additives to the polyamic acid.

Some examples of an acid anhydride (dianhydride) that can be used here include PMDA (pyromellitic dianhydride), PA (phthalic anhydride), BPDA (3,3′4,4′-biphenyltertracarboxylic dianhydride), BTDA (3,3′4,4′-benxophenonetetracarboxylic dianhydride), ODPA (4′4-oxydiphthalic anhydride), TMEG (trimellitic ethylene glygol), BPADA (4,4″-(4′4-isopropylbiphenoxy)bi phthalic anhydride), 4-PEPA (4-phenylethynyl phthalic anhydride), 6FDA (perfluoroisopropylidene containing acid dianhydride), TMA (trimellitic anhydride), etc.

Some examples of diamine monomers that can be3 used here include ODA (4,4′-diamino diphenyl), p-PDA (p-phenyl diamine), 4,4′-ODA 4,4′-oxydianiline, BAPP (2,2-bis(4-(4-aminophenoxy)-phenyl)propane, p-MDA (p-methylenedianiline), GAPD (propyltetramethyl disiloxane), jeffamine (AP-22 polyaromatic amine), TPE-R, DDS (4,4′-diaminodiphenyl sulfone), TFDB (2,2′-bis(trifluoromethyl)-4,4′-diaminobiphenyl), Triazole (3,5-diamino-1,2,4-triazole), MDA (4,4′diamino-diphenyl methane), OTB (3,3′-dimethyl benzidine), etc.

To be more specific, the diamine monomers ODA (4,4′-diamino diphenyl), p-PDA (p-phenyl diamine), and 4,4′-ODA (4,4′-oxydianiline) may first be placed in an NMP solvent for first polymerization, and the acid anhydrides PMDA (Pyromellitic dianhydride), PA (phthalic anhydride), and BPDA (3,3′4,4′-biphenyltertracarboxylic dianhydride) may be placed in an NMP solvent for second polymerization.

Although this embodiment is described with the polymerization divided into the first polymerization and second polymerization, it is possible to perform the polymerization in one round with the amine and acid anhydride placed in an NMP solvent.

Afterwards, the products of the first and second polymerization may be mixed together to obtain a polyamic acid, and additives may be included to obtain a desired composition.

The content of the composition in this example is 35% of polyimide, 1% of the defoaming agent MOUSSEX, 1% of the leveling agent MODAREZ, 1% of the dispersing agent SYNTHRO, 3% modified polyimide, 3% silica, and the remainder of the solvent NMP.

A description is provided below, with reference to FIG. 2, of a process for applying the liquid polyimide composition for a coverlay obtained as above on a PCB.

First, a mask matching the circuits of the PCB may be fabricated on the printing equipment. The mask may include portions that are opened in correspondence to the circuit patterns. Using silkscreen printing, the liquid polyimide composition may be coated onto the open portions.

After the coating, the composition may be fully cured in an oven at a temperature of 200° C. or lower. To be more specific, the curing may be performed with the temperature adjusted in a stepwise manner, starting from 100° C. to 120° C., 160° C., and 200° C. The total duration of the thermal curing may be 90 minutes.

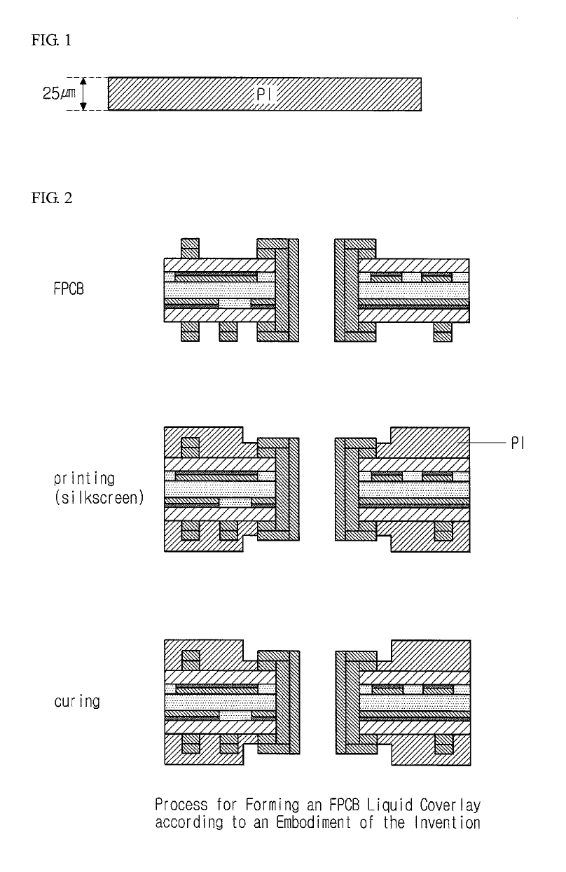

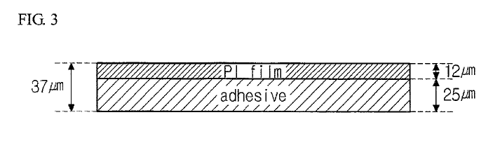

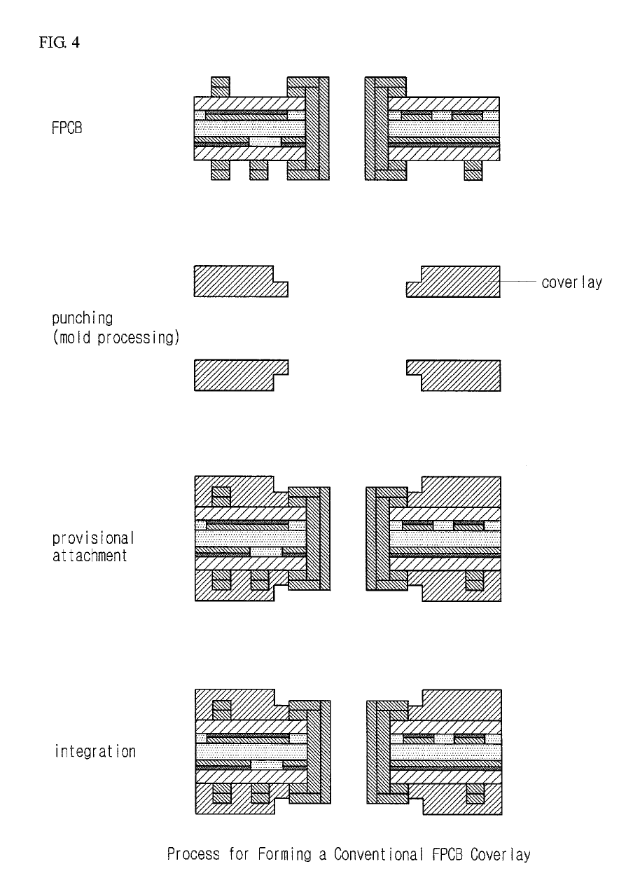

The thickness of a polyimide coverlay layer obtained as above may be 25 μm, as illustrated in FIG. 1.

The process times for the above may include 30 minutes for the printing process and 90 minutes for the curing process, so that the total duration may only be about 2 hours, which is a significant reduction compared to existing processes. This may also provide a reduction in processing costs.

Also, the liquid polyimide coverlay obtained as above has a one-layer structure as illustrated in FIG. 1, providing a reduced thickness compared to the conventional coverlay film having a two-layered (PI/adhesive) structure. Thus, there is an increased degree of freedom in design, as well as superior flexibility and electrical properties.

Moreover, since the present method includes just two steps of processing, there is no need for integration equipment, molding equipment, etc., allowing reductions in costs associated with investments for machinery. This in turn may allow increased space utility in the manufacturing plant, leading to greater productivity. Also, the labor hitherto used for the provisional attachment, which requires manual operations, can be utilized for other processes, resulting in a considerable effect in terms of overall reduction in cost.

Below, test results are provided which compare the properties of a coverlay of a one-layer structure produced according to an embodiment of the invention with the properties of a conventional coverlay film.

### (1) Electrical Properties

TABLE 1
Electrical Properties of a Liquid Polyimide Coverlay
based on an Embodiment of the Invention

| | Test Condition | | | |
|---|---|---|---|---|
| Item | Condition | Method | Unit | Value |
| Dielectric constant | 1 MHz | ASTM D 150 | — | 3.5 |
| Dissipation factor | 1 MHz | ASTM D 150 | — | 0.007 |
| Water Absorption | D-24/23 | PM method | % | 1.9 |
| Surface Resistance | C24/23/50 | JIS C 6481 | Ω | 1 × 10¹⁴ |
| Volume Resistance | C24/23/50 | JIS C 6471 | Ω · cm | 1 × 10¹⁶ |
| Chemical | MEK/IPA/ | JIS C 5016 | % | OK (>80%) |
| Resistance | CH2Cl2/ | | | |
| | 2N HCl/ | | | |
| | 2N NaOH | | | |

TABLE 2
Electrical Properties of a Conventional
Coverlay Film as a Comparative Example

| | Test Condition | | | |
|---|---|---|---|---|
| Item | Condition | Method | Unit | Value |
| Dielectric constant | 1 MHz | ASTM D 150 | — | 4.0 |
| Dissipation factor | 1 MHz | ASTM D 150 | — | 0.04 |
| Water Absorption | D-24/23 | PM method | % | 1.9 |
| Surface Resistance | C24/23/50 | JIS C 6481 | Ω | 1 × 10¹²~ |
| | | | | 1 × 10¹⁴ |
| Volume Resistance | C24/23/50 | JIS C 6471 | Ω · cm | 1 × 10¹³~ |
| | | | | 1 × 10¹⁴ |
| Chemical | MEK/IPA/ | JIS C 5016 | % | OK (>80%) |
| Resistance | CH2Cl2/ | | | |
| | 2N HCl/ | | | |
| | 2N NaOH | | | |

### (2) Thermal Properties

TABLE 3
Thermal Properties of a Liquid Polyimide Coverlay
based on an Embodiment of the Invention

| | Test Condition | | | |
|---|---|---|---|---|
| Item | Condition | Method | Unit | Value |
| Tg | — | DMA | ° C. | 300 |
| CTE | 100~200° C. | TMA | ppm/° C. | 24 |
| Flammability | — | UL method | VTM-0 | VTM-0 |
| | | (UL94) | | |
| Solder Float | 300° C./30 sec | JIS C 6471 | kgf/cm | OK |
| Resistance | | | | |
| Dimension | Before Heating | JIS C 6471 | % | MD: 0.02 |
| Stability | | | | TD: −0.01 |
| | After Heating | | % | MD: 0.03 |
| | (300° C./30 sec) | | | TD: −0.01 |

TABLE 4
Thermal Properties of a Conventional Coverlay
Film as a Comparative Example

| | Test Condition | | | |
|---|---|---|---|---|
| Item | Condition | Method | Unit | Value |
| Tg | — | DMA | ° C. | 150 |
| CTE | 100~200° C. | TMA | ppm/° C. | 24 |
| Flammability | — | UL method | VTM-0 | VTM-0 |
| | | (UL94) | | |
| Solder Float | 300° C./30 sec | JIS C 6471 | kgf/cm | OK |
| Resistance | | | | |
| Dimension | Before Heating | JIS C 6471 | % | MD: 0.02 |
| Stability | | | | TD: −0.01 |
| | After Heating | | % | MD: 0.03 |
| | (300° C./30 sec) | | | TD: −0.01 |

As can be seen in Table 1 and Table 2, the liquid polyimide has a dielectric constant of 3.5 and a dissipation factor of 0.007, whereas the conventional coverlay film has a dielectric constant of 4.0 and a dissipation factor of 0.04, so that the liquid polyimide is far more superior. It is well known that a lower dielectric constant allows better electrical signal properties and that a lower dissipation factor allows a lower rate of dissipation during signal transmissions.

Higher values for surface resistance and volume resistance allow superior insulation properties. The liquid polyimide according to an embodiment of the invention has a surface resistance of 1×10¹⁴ and a volume resistance of 1×10¹⁶ whereas the conventional coverlay film has a surface resistance of 1×10¹³˜1×10¹⁴ and a volume resistance of 1×10¹³˜10¹⁴, showing the liquid polyimide of the present embodiment to be superior to the conventional coverlay film.

Looking at the thermal properties shown in Table 3 and Table 4, the glass transition temperature (Tg) of the liquid polyimide based on an embodiment of the invention is 300° C., which is significantly higher than the glass transition temperature (Tg) of 150° C. of the epoxy used for the adhesive layer of the conventional coverlay film, showing that the liquid polyimide based on an embodiment of the invention has considerably superior thermal resistance.

What is claimed is:

1. A composition for a PCB coverlay, the composition comprising:
10.0˜45.0 wt % of polyimide, 0.01˜5.0 wt % of a defoaming agent, 0.01˜5.0 wt % of a leveling agent, 0.01˜5.0 wt % of a dispersing agent, 0.1˜15.0 wt % of modified polyimide, and a remainder of a solvent.

2. The composition of claim 1, further comprising 1.0˜15.0 wt % of silica.

3. The composition of claim 1, wherein the polyimide is formed by a polymerization of an acid anhydride and amine.

4. The composition of claim 3, wherein the acid anhydride is any one of PMDA (pyromellitic dianhydride), PA (phthalic anhydride), BPDA (3,3′4,4′-biphenyltertracarboxylic dianhydride), BTDA (3,3′4,4′-benxophenonetetracarboxylic dianhydride), ODPA (4′4-oxydiphthalic anhydride), TMEG (trimellitic ethylene glygol), BPADA (4,4″-(4′4-isopropylbiphenoxy)bi phthalic anhydride), 4-PEPA (4-phenylethynyl phthalic anhydride), 6FDA (perfluoroisopropylidene containing acid dianhydride), and TMA (trimellitic anhydride).

5. The composition of claim 3, wherein the amine is any one of ODA (4,4′-diamino diphenyl), p-PDA (p-phenyl diamine), 4,4′-ODA 4,4′-oxydianiline, BAPP (2,2-bis(4-(4-aminophenoxy)-phenyl)propane, p-MDA (p-methylenedianiline), GAPD (propyltetramethyl disiloxane), jeffamine (AP-22 polyaromatic amine), TPE-R, DDS (4,4′-diaminodiphenyl sulfone), TFDB (2,2′-bis(trifluoromethyl)-4,4′-diaminobiphenyl), Triazole (3,5-diamino-1,2,4-triazole), MDA (4,4′diaminodiphenyl methane), and OTB (3,3′-dimethyl benzidine).

6. A method of producing an FPCB coverlay, the method comprising:
placing amine and an acid anhydride in a reaction solvent and subjecting to first polymerization;
placing an acid anhydride in a separate reaction solvent subjecting to second polymerization;
forming a polyamic acid by mixing a product of the first polymerization with a product of the second polymerization; and
adding a defoaming agent, a leveling agent, a dispersing agent, and modified polyimide to the polyamic acid.

7. The method of claim 6, wherein a content of the polyimide is 10.0˜45.0 wt %, a content of the defoaming agent is 0.01˜5.0 wt %, a content of the leveling agent is 0.01˜5.0 wt %, a content of the dispersing agent is 0.01˜5.0 wt %, and a content of the modified polyimide is 0.1˜15.0 wt %.

8. The method of claim 6, wherein the polyimide further comprises 1.0˜15.0 wt % of silica.

9. A method of forming a polyimide coverlay on an FPCB, the method comprising:
preparing a mask over a circuit of an FPCB, the mask having a desired printing pattern;
applying the liquid polyimide composition of claim 1 over an opening of the mask; and
curing the PCB having the polyimide composition applied thereto.

10. The method of claim 9, wherein the printing is performed by silkscreen printing.

11. The method of claim 9, wherein the curing process is performed in an oven at about 200° C.

12. The method of claim 9, wherein the cured polyimide composition has a thickness of 10˜60 μm.
